(19) United States
(12) Patent Application Publication
(10) Pub. No.: US 2022/0398226 A1
(43) Pub. Date: Dec. 15, 2022

(54) METHODS FOR ACCURATE DOWNTIME CACULATION

(71) Applicant: TBCASOFT, INC., Sunnyvale, CA (US)

(72) Inventors: Chiahsin LI, San Jose, CA (US); Kaidi DU, Santa Clara, CA (US); Shieng-Chyurn JANG, Newark, CA (US)

(21) Appl. No.: 17/830,360

(22) Filed: Jun. 2, 2022

Related U.S. Application Data
(60) Provisional application No. 63/195,720, filed on Jun. 2, 2021.

(51) Int. Cl. G06F 16/21; G06F 16/27

(52) U.S. Cl. CPC G06F 16/21; G06F 16/27

(57) ABSTRACT

The present invention relates to methods for accurate downtime calculation. The method comprises filtering an input signal from a system by a closing process and an opening process to generate a first smoothed signal. The method may include applying moving average filtering to the first smoothed signal to generate a second smoothed signal. The method may further include generating the morphology event labels and the average event labels of the signal based on the first and second smoothed signals, and determining the downtime intervals by the event labels.

### RELATED APPLICATION

This application claims the benefit of the U.S. provisional application 63/195,720 filed on Jun. 2, 2021, titled “METHOD AND SYSTEMS TO MEASURE SERVICE LEVEL OBJECTIONS,” which is incorporated herein by reference at its entirety.

### BACKGROUND OF THE INVENTION

### Field of the Invention

The present invention relates to methods for accurate downtime calculation; more particularly, to methods for downtime calculation of systems with a stable baseline signal, especially for distributed ledger systems monitoring block height increments as an input data to determine the downtime interval and total downtime.

### DESCRIPTION OF RELATED ART

A service-level objective (SLO) is a key element of a service-level agreement (SLA) between a service provider and a customer. SLOs are agreed upon as a means of measuring the performance of the service provider and are outlined as a way of avoiding disputes between the two parties owing to misunderstanding. Several types of measures are frequently applied in SLOs, such as availability, service desk response, response time, etc. Among them, availability is the degree to which a system or equipment is in a specified operable and committable state at the start of a mission when the mission is called. Therefore, for setting feasible SLOs, it is crucial for a service provider to accurately measure the availability of the provided services.

Downtime refers to periods when a system is unavailable or offline, which is usually a result of the system failing to function because of an unplanned event or a routine maintenance. The measurement of system downtime is a direct way to know the availability of the system. For a system normally operates with a stable baseline for specific signals (e.g. the voltage in a power supply), the measurement of system downtime can be achieve by monitoring the signal from the system, and the downtime can be claimed when the signal deviates from the baseline and does not recover within a predetermined short period.

As the development of blockchain techniques, the clearance and settlement of digital property using blockchain consensus in the network within a business alliance becomes available, as provided in International Application PCT/US2017/012635 filed on Jan. 6, 2017. This method, however, requires a majority of nodes to operate normally in order to reach a consensus in the transaction. To evaluate the availability of this service, a probabilistic model may be applied to check the status of the validator nodes, and thus to check the overall network status. In the probabilistic model, it regularly counts the number of healthy validators on the network once every a specific time (e.g. once every minute). If more than a specific number of validators (e.g. ½ or ⅓) are down, the network halts, and the system is declared to be in downtime.

The drawback of the probabilistic model is that it might have a higher chance to report false positives downtime, which means that the network is still up but is reported down. It is especially the case when signals from some nodes are not sent to the network administrator perfectly. The probabilistic model is the estimated measure of the network performance using signals from the agent coordinator. For example, if more than ⅓ of the signals are missing due to the temporary down of the agent coordinator but the actual network is still growing, the probabilistic model will report that the network is down.

Accordingly, it is desirable to develop methods to improve the system downtime calculation in the measure of service level objection.

### SUMMARY OF THE INVENTION

To resolve the problems, the present invention provides a method for accurate downtime calculation based on measured block height increments as an input data to determine the downtime interval and total downtime of the system.

The present disclosure described a method for signal processing, comprising filtering an input signal from a system by a closing process and an opening process to generate a first smoothed signal. The closing process comprises a first dilation process followed by a first erosion process, and the opening process comprises a second erosion process followed by a second dilation process.

In one embodiment, each of the first dilation process and the second dilation process is performed by outputting its local maximum within a normal dilation window for each data point of the input signal, and each of the first erosion process and the second erosion process is performed by outputting its local minimum within a normal erosion window for each data point of the input signal.

In one embodiment, the method of the present invention further comprises generating a second smoothed signal by a moving average filter, wherein each data point of the second smoothed signal is generated by calculating the average value of all local data points within an averaging window for each data point of the first smoothed signal, and outputting the averaging result.

In one embodiment, the method further comprising: (1) generating a series of morphology event labels representing system down events or up events based on the first smoothed signal; (2) generating a series of average event labels representing system down events or up events based on the second smoothed signal. The series of morphology event labels indicating the positions of sharp downward steps and sharp upward steps of the first smoothed signal, and the series of average event labels indicating the positions where the second smoothed signal crosses an average threshold value.

In one embodiment, the series of average up labels further comprise a series of artificial up labels indicating the second smoothed signal goes above the average threshold value following a morphology down label.

In one embodiment, the method further comprises determining one or more downtime intervals based on the morphology event labels and the average event labels, wherein each of the downtime intervals indicates the interval when the system does not operate normally.

In one embodiment, the downtime interval is determined by a state machine with multiple states with the steps of: (1) integrating the morphology event labels and the average event labels into the same index based on their corresponding positions; (2) determining the state of the first position in region of interest; (3) determining the state of each position from the second position to the last position in region of interest based on the state of its previous position and the existence of a morphology event label or an average event label at that position; and (4) determining the downtime interval based on the states of all positions in region of interest.

In one embodiment, the states in the state machine comprise Up state, Metastable Down state and Deep Down state, wherein the state of the first position is set to Up state; and the state of the remaining position are determined by the following rules: (1) if no morphology event label or average event label is identified at that position, the state of the position is the same as the previous position; (2) if an average up label is identified at that position, the state of the position is Up state; (3) if an average down label is identified at that position, the state of the position is Deep Down state; (4) if the previous position is Up state or Metastable Down state, and a morphology up label is identified at that position, the state of the position is Up state; (5) if the previous position is Up state or Metastable Down state, and a morphology down label is identified at that position, the state of the position is Metastable Down state; and (6) if the previous position is Deep Down state and a morphology up label or a morphology down label is identified at that position, the state of the position is Deep Down state.

In one embodiment, the downtime interval is determined by: (1) identifying the positions determined as Metastable Down state or Deep Down state where the previous state is Up state as the starting points of downtime; (2) identifying the positions determined as Up state where the previous state is Metastable Down state or Deep Down state as the ending points of downtime; and (3) pairing all staring points of downtime with their following ending points of downtime to identify all downtime intervals.

### BRIEF DESCRIPTION OF THE DRAWINGS

FIG. 1 shows the flow chart of the method for accurate downtime calculation.

FIG. 2 shows the original input signal implementing downtime calculation in the example.

FIG. 3 shows the first dilation signal produced by dilating the input signal with r_left=M_r=3 and r_right=M_r=3.

FIG. 4 shows the first erosion signal produced by eroding the first dilation signal with r_left=M_r=3 and r_right=M_r=3.

FIG. 5 shows the second erosion signal produced by eroding the first erosion signal with r_left=M_r=3 and r_right=M_r=3.

FIG. 6 shows the second dilation signal produced by dilating the second erosion signal with r_left=M_r=3 and r_right=M_r=3. The resulting signal is the first smoothed signal.

FIG. 7 shows the bias dilated signal produced by dilating the first smoothed signal with r_left=ceil(½*M_r)=ceil(½*3)=2 and r_right=0.

FIG. 8 shows the down spike signal produced by subtracting the first smoothed signal from the bias dilated signal.

FIG. 9 shows the bias eroded signal produced by eroding the first smoothed signal with r_left=ceil(½*M_r)=ceil(½*3)=2 and r_right=0.

FIG. 10 shows the up spike signal produced by subtracting the bias eroded signal from the first smoothed signal.

FIG. 11 shows the second smoothed signal produced by applying a moving average process with A_r=6 on the first smoothed signal.

FIG. 12 shows the scanning of down spikes with M_threshold=6 to get morphology down label(s).

FIG. 13 shows the scanning of up spikes with M_threshold=6 to get morphology up label(s).

FIG. 14 shows the morphology event labels generated by the morphology event generator.

FIG. 15 shows the scanning of dip average signals with A_threshold=8 to get average event labels.

FIG. 16 shows the average event labels generated by the average event generator.

FIG. 17 shows a special case when a morphology down label exists due to a rapid drop but Up label misses due to a gradual incline and the second smoothed signal is all above the watermark.

FIG. 18 shows the finite state machine to analyze filter labels in the downtime interval detection.

FIG. 19 shows the detected downtime intervals [301, 361] for the original input signal with M_r=3, M_threshold=6, A_R=6, and A_threshold=8.

FIG. 20 shows periodically running intervals for downtime determination.

### DETAILED DESCRIPTION OF PREFERRED EMBODIMENTS

The terminology used in the description presented below is intended to be interpreted in its broadest reasonable manner, even though it is used in conjunction with a detailed description of certain specific embodiments of the technology. Certain terms may even be emphasized below; however, any terminology intended to be interpreted in any restricted manner will be specifically defined as such in this Detailed Description section.

The embodiments introduced below can be implemented by programmable circuitry programmed or configured by software and/or firmware, or entirely by special-purpose circuitry, or in a combination of such forms. Such special-purpose circuitry (if any) can be in the form of, for example, one or more application-specific integrated circuits (ASICs), programmable logic devices (PLDs), field-programmable gate arrays (FPGAs), etc.

In the present disclosure, the block height increments of the distributed ledger are used as the input data to determine the downtime interval and total downtime of the system if downtimes exist. Theoretically, the ledger number should monotonically increase at a constant rate when the network is up. The block height increment curve, i.e. ledger number deltas, should stay around a constant value. It means the derivative of the ledger numbers is a constant. On the other hand, if the block height increment curve has a dramatic drop and remains a comparably small value for a while (the depth of the drop passes a predefined threshold and the width of the down value stays longer than another predefined value), a network downtime will be declared by the method of this invention. However, it should be noted that the method in this disclosure is applicable to any systems with stable baseline signals, and is not limited to the example provided herein.

The method for downtime determination disclosed herein is designed to be able to detect the following event of the system: (1) a sudden failure that lasts for a while; (2) a slowly deteriorating failure that lasts for a while; (3) a quick recovery from a certain time of failure; and (4) a gradual recovery from a certain time of failure. In addition, noise such as small and short system glitch and network fluctuation, should be eliminated to avoid false downtime calculation.

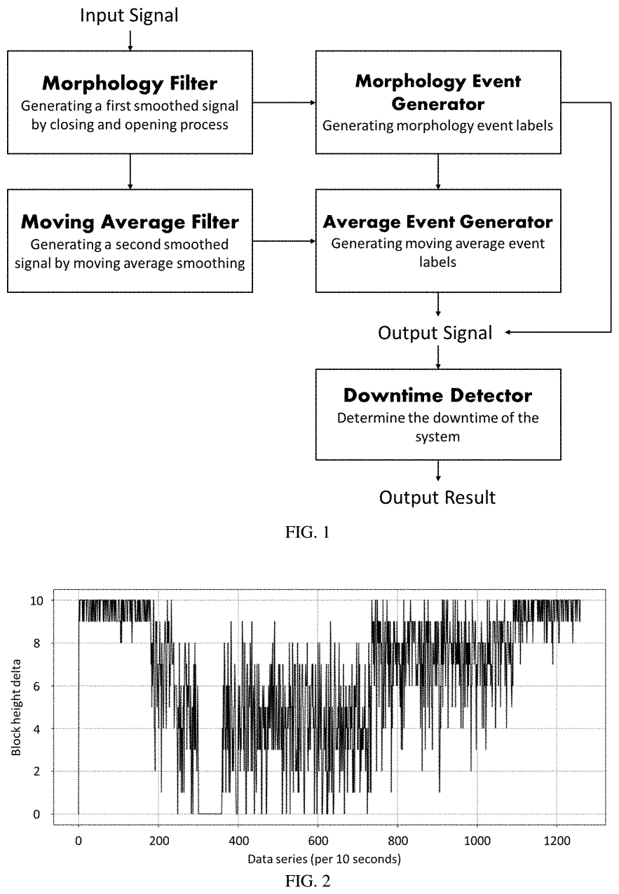

FIG. 1 is a flow chart for the downtime determination method. First of all, a morphology filter receives the input signal and generates a first smoothed (morphology smoothed) signal by closing process and opening process. The generated first smoothed signal then is provided to a moving average filter, where the moving average filter used the first smoothed signal to generate a second smoothed signal (moving average signal) by calculating the moving average of the first smoothed signal. The first smoothed signal is also provided to the morphology generator to generate a series of morphology event labels indicating rapid drop or lift of the signal. After that, an average event generator receives both the morphology event labels from the morphology generator and the second smoothed signal from the moving average filter to generate a series of moving average event labels indicating gradual decline or rise of the signal. Both the morphology event labels and the moving average event labels are provided to a downtime detector to determine the existence and the duration of the downtime of the system.

A morphology filter refers to a machine or a module implemented in a programmable circuit which performs the function of morphology filtering as described above. The morphology filter may also be able to further process the first smoothed signal to find down-spikes and up-spikes for the first smoothed signal. A moving average filter refers to a machine or a module implemented in a programmable circuit which performs the function of moving average calculation. A morphology event generator refers to a machine or a module implemented in a programmable circuit which generates morphology event labels indicating rapid drop or lift of the input signal. The morphology event labels may be further divided into (1) morphology down labels indicating the occurrence of a rapid drop, and (2) morphology up labels indicating the occurrence of a rapid lift. An average morphology event generator refers to a machine or a module implemented in a programmable circuit which generates moving average event labels indicating a gradual decline or rise of the input signal. The moving average event labels may be further divided into (1) average down labels indicating the signal gradually falls below the watermark, and (2) average up labels indicating the signal gradually rises above the watermark. The moving average event generator may also receive the morphology labels from a morphology event generator to generate a series of artificial up labels besides the normal average up labels to avoid miscalculation of system downtime. A downtime detector refers to a machine or a module implemented in a programmable circuit which integrates the event labels from a morphology event generator and an average event generator to determine the downtime intervals and total downtime of the system. The downtime detector may employ a finite state machine to determine the state of the system along with the time series, and calculate the downtime based on the states determined.

In general, the method comprises generating a first smoothed signal for an input signal by closing and opening process, generating a second smoothed signal for the first smoothed signal by moving average smoothing, generating morphology event labels and average event labels based on the first and second smoothed signals, and using the generated labels to determine the downtime interval and total downtime of the system.

Firstly, the present invention provides a method for signal processing by a morphology filter, comprising filtering an input signal with a closing process and an opening process to generate a first smoothed signal, wherein the closing process comprises a dilation process followed by an erosion process, and the opening process comprises an erosion process followed by a dilation process. In one embodiment of the invention, the dilation process is performed by finding the local maximum for all data points within a normal dilation window for each data point of the input signal in region of interest, and the erosion process is performed by finding the local minimum for all data points within a normal erosion window, respectively. The dilation process aims to remove upward noise spikes, and the erosion process aims to remove downward noise spikes. The normal dilation and erosion windows applied for local maximum/minimum calculation are generally small and extend only several points from the position of the input signal. The method disclosed herein can be a closing process followed by an opening process (i.e. dilation, erosion, erosion and dilation in sequential), or it can also be an opening process followed by a closing process (i.e. erosion, dilation, dilation and erosion in sequential). Both procedures should yield similar results to each other. The region of interest is usually the region where the downtime interval will be determined. With the morphology filtering process, the noise signals caused by glitches or temporarily down the network monitor can be removed.

The generated first smoothed signal is then sent to a moving average filter to generate a second smoothed signal. The second smoothed signal is generated by calculating the average value of all local data points within a predetermined averaging window for each corresponding data point of the first smoothed signal, with the corresponding data point of the first smoothed signal placed at the center of the predetermined averaging window. The aim of applying a moving average filter is to find the “trend” of the signal and to smooth the local fluctuation of the first smoothed signal.

The first smoothed signal (morphology smoothed signal) and the second smoothed signal (moving average smoothed signal) are then used to generate a series of morphology event labels and average event labels representing the positions where the system goes down and goes up. The morphology event labels are generated based on the first smoothed signal by a morphology event generator. The morphology labels indicate system down events or up events by labeling the positions of sharp downward steps and sharp upward steps of the first smoothed signal. In one embodiment of the invention, the morphology event labels are divided into two groups: morphology down labels indicating the positions of sharp downward steps of the first smoothed signal, and morphology up labels indicating the positions of sharp upward steps of the first smoothed signal. On the other hand, the second smoothed signal is used by an average event generator to generate a series of average event labels indicating system down events or up events, wherein the average event labels are the positions where the second smoothed signal crosses a predetermined average threshold value. In one embodiment, the average event labels are divided into two groups: average down labels indicating the positions where the second smoothed signal crosses the average threshold value from above to below, and average up labels indicating the positions where the second smoothed signal crosses the average threshold value from below to above.

In an embodiment of the present invention, the positions of the down morphology labels which represent the positions of sharp downward steps are identified by (1) performing a bias dilation process to the first smoothed signal to generate a bias dilated signal; (2) subtracting all data points of the first smoothed signal from the corresponding data points of the bias dilated signal to obtain a first spike signal representing the positions of downward steps; and (3) finding the positions where the value of first spike signal is equal to or above a predetermined down-spike threshold value. The positions where the first spike signal goes above the down-spike threshold value are defined as the positions of morphology down events. Likewise, the positions of up morphology labels representing the positions of sharp upward steps are identified by (1) performing a bias erosion process to the first smoothed signal to generate a bias erosion signal; (2) subtracting all data points of the bias eroded signal from the corresponding data points of the first smoothed signal to obtain a second spike signal representing the position of upward steps; and (3) finding the positions where the value of the second spike signal is equal to or above a predetermined up-spike threshold value. The positions where the second spike signal goes above the up-spike threshold value are defined as the positions of morphology up events. The bias dilation process and bias erosion process are similar to the normal dilation and erosion process described above, except that the data point of the input first smoothed signal is placed at the last position of the dilation or erosion window instead of placing at the center. Furthermore, the bias dilation/erosion window used in the bias dilation/erosion process is smaller than half of the normal dilation/erosion window in order to accurately extract the positions of sharp downward/upward steps.

In one another embodiment, the series of average up labels further comprise a series of artificial up labels indicating the second smoothed signal goes above the average threshold value following a morphology down label. In this embodiment, the generated morphology event labels are received by the average event generator and used to generate a series of artificial up labels, wherein the artificial up labels are generated when a morphology down label is identified but no average event label exists in a predetermined range following the morphology down label. This can be determined by checking all values of the second smoothed signal within a predetermined range from which the morphology down label is identified. If all the checked values are above the average threshold value, an artificial up label is generated correspondingly. In the following downtime determination step, the generated artificial up labels are treated as normal average up labels. The introduction of the artificial up labels is to avoid a special case that when the signal drops abruptly and recovers relatively smoothly, and only a morphology down label is generated but no average up label exists to declare an uptime (i.e. the end of a downtime interval) when the network actually recovers, as shown in FIG. 17. In other words, if the signal has a rapid drop but a gradual incline, there might be only a down type filter label to indicate the start of a downtime, but missing an up type filter label to indicate the signal goes back to normal.

The application of both morphology-based filter and moving-average-based filter to generate both morphology event labels and average event labels have the advantage of finding the true starting point of a downtime more sensitively while preventing the false-positive results from noise signals. Generally speaking, for a moving average filter and the morphology event labels, the smaller the threshold values are, the more sensitive the downtime detection will be, and also more likely to be influenced by the noise signals (e.g. a glitch). On the other hand, if the threshold values are set to be large, the detected downtime will always be declared much later than the actual downtime. Consequently, to achieve a satisfied sensitivity, morphology-based filters are applied, and moving-average-based filters can confirm that the downtime results from morphology-based filters are true to avoid false positives as much as possible.

Lastly, a downtime detector integrates the morphology event labels and the average event labels into the same index based on their corresponding positions, and determines the downtime interval based on the morphology event labels and the average event labels. In the embodiment where the artificial up labels are generated, the artificial up labels are treated the same as the average up labels. In details, the downtime determination process includes (1) determining the state of the first position; (2) determining the state of each position from the second position to the last position in region of interest based on the state of its previous position and the existence of a morphology event label or an average event label at that position; and (3) determining the downtime interval based on the states of all positions in region of interest. To prevent the problems caused when a morphology event label and an event average label present at the same position, in an embodiment of the invention, when integrating the series of morphology event labels and the series of average event labels, the average event label at the position is entered and the morphology event label at the same position is discarded.

The determination of the downtime interval can be performed by a finite state machine with three available states: “Up” state, “Metastable Down” state, and “Deep Down” state. Each state represents the status of the signal. Up state represents a status when the signal stays around the baseline; whereas Metastable Down and Deep Down state (collectively “Down states”) represent a status when the signal stays below and far off the baseline. The state of the first position in the region of interest is set as an “Up” state, and the states of each of the following positions are determined by the state of its previous position and the existence of a morphology event label or an average event label at that position. The rules of determining the states are as follows:
(1) If no morphology event label, average event label or the artificial up label is identified at that position, the state of the position is the same as the previous position.
(2) If an average up label (including an artificial up label) is identified at that position, the state of the position is Up state.
(3) If an average down label is identified at that position, the state of the position is Deep Down state.
(4) If the previous position is Up state or Metastable Down state, and a morphology up label is identified at that position, the state of the position is Up state.
(5) If the previous position is Up state or Metastable Down state, and a morphology down label is identified at that position, the state of the position is “metastable down state”.
(6) If the previous position is Deep Down state and a morphology up label or a morphology down label is identified at that position, the state of the position is Deep Down state.

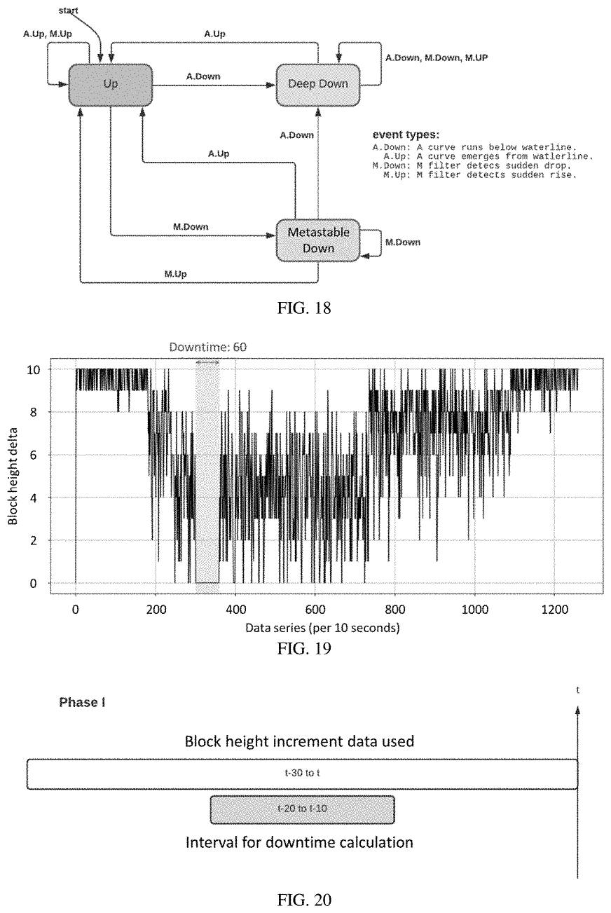

The rules above can be summarized as shown in Table 1 and FIG. 18. When the downtime intervals are determined, the length of each downtime interval, and the total downtime of the system can be calculated easily.

TABLE 1
State-transition table of the finite state machine to
process filter labels in FIG. 18

| | | Next State |
|---|---|---|
| Current State | Input Label | (Output) |
| Up | M.Up | Up |
| | M.Down | Metastable Down |
| | A.Up | Up |
| | A.Down | Deep Down |
| Metastable | M.Up | Up |
| Down | M.Down | Metastable Down |
| | A.Up | Up |
| | A.Down | Deep Down |
| Deep Down | M.Up | Deep Down |
| | M.Down | Deep Down |
| | A.Up | Up |
| | A.Down | Deep Down |

Next, the downtime interval is determined by (1) identifying the positions determined as Metastable Down state or Deep Down state where the previous state is Up state as the starting points of downtime; (2) identifying the positions determined as Up state where the previous state is Metastable Down state or Deep Down state as the ending points of downtime; and (3) pairing all staring points of downtime with their following ending points of downtime to identify all downtime intervals. A pair of data points are included in a downtime interval, which represent the starting point and the ending point of the downtime. Based on the downtime interval, the length of each downtime, and the length of total system downtime within the interval of downtime detection, can both be easily calculated.

In one embodiment, to avoid errors due to the boundary conditions, the interval of downtime determination is smaller than the interval of state determination, so that the downtime detector only uses the middle part of the states determined by the state machine to generate the downtime interval. Therefore, the uncertainty of the state caused by the boundary can be avoided.

### EXAMPLE

The following example is provided to further illustrate the present invention. In the example system, the core monitor receives a signal from the network every 10 seconds representing the block number of the distributed ledger. Theoretically, the ledger number should monotonically increase at a constant rate when the system works normally. Therefore, by calculating the block high increment (the block number of a specific point minus the number of the previous point) to every point, a block high increment curve is obtained as the input signal, as shown in FIG. 2.

### Signal Smoothing by Morphology Filter

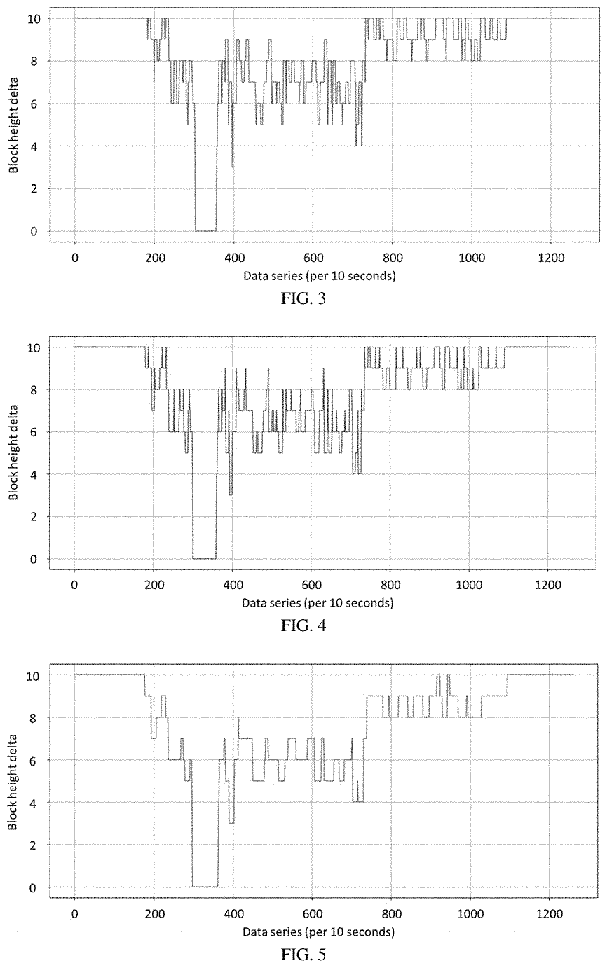

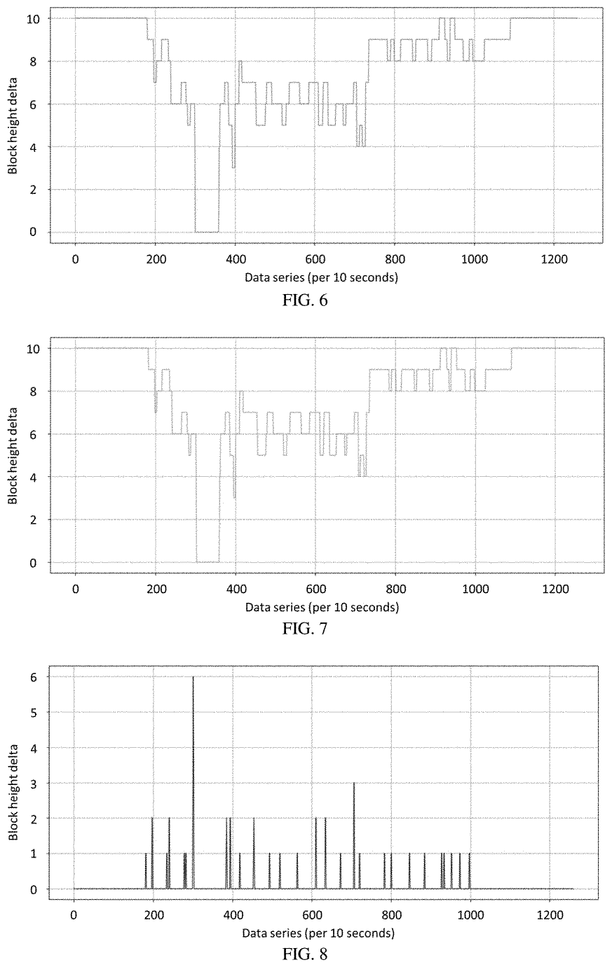

The input signal was then filtered by a morphology filter, which is a collection of non-linear operations intends to smooth out the noise from the original curve and to produce the result that indicates the radical changes on the curve. Two types of morphology-based operations, dilation and erosion, were implemented. The dilation operation is to find the local maximum value on the data points within a predetermined dilation window, i.e. y[i]=max(x[i−r_left: i+r_right]), where x[ ] is the input data point value and y[ ] is the output data point value, with the boundary condition: “if i−r_left<0, use 0; if i+r_right>the length of x−1, use the length of the x−1.” In this example, the values of both r_left (left radius) and r_right (right radius) are set to 3 (r_left=r_right=M_r=3, wherein M_r was defined as the radius), and the dilation window contained 7 data points in total. With the parameters of r_left=r_right=M_r=3, the position of each output data point is at the center of corresponding input window. Similarly, the erosion operation is to find the local minimum value on the data points within a predetermined erosion window, i.e. y[i]=min(x[i−r_left: i+r_right]), where x[ ] is the input data point value and y[ ] is the output data point value, with the boundary condition: “if i−r_left<0, use 0; if i+r_right>the length of x−1, use the length of the x−1.” As described above, the values of both r_left and r_right are set to 3, and the erosion window also contained 7 data points in total. In conclusion, a 4-step procedure comprising first dilation, first erosion, second erosion and second dilation was performed. The result of the processed signal after first dilation, first erosion, second erosion and second dilation are shown in FIG. 3, FIG. 4, FIG. 5 and FIG. 6, respectively. FIG. 6 is the first smoothed signal obtained by the dilation and erosion processes described above. It can be seen that most of the noises in the original input signal (FIG. 2) were eliminated. Snippet 2-5 provides the pseudo code for this example implementing the functions of dilation operation, finding maximum for dilation, erosion operation, finding minimum for erosion, respectively.

### Finding Down Spikes and Up Spikes

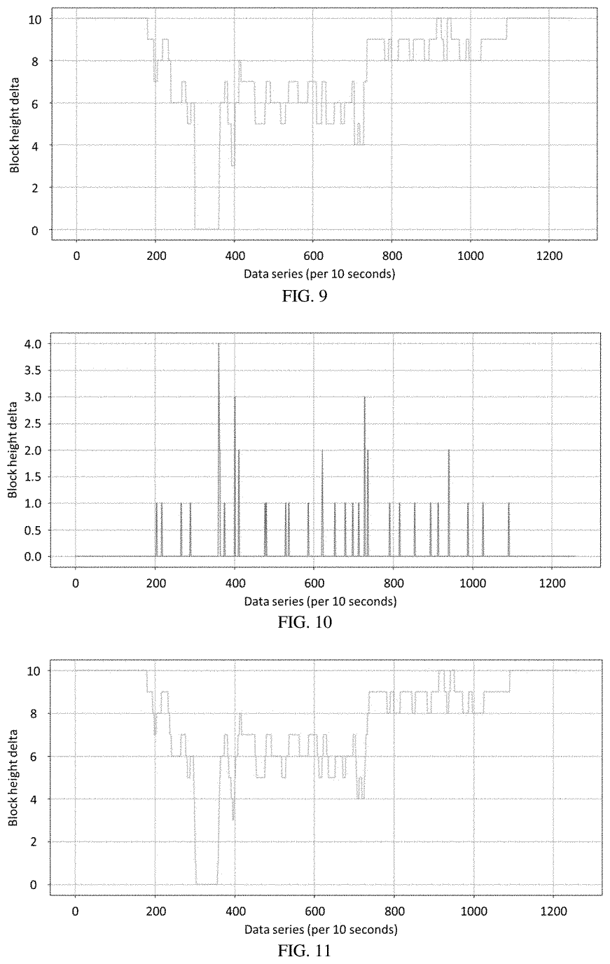

To find the morphology labels indicating downward steps, firstly the morphology filter performed a bias dilation process on the first smoothed signal with left radius r_left=ceil(½*M_r)=2 and right radius r_right=0. The bias dilation window contains 3 data points and the output is at the last position of the bias dilation window. The bias dilation process utilized the same Python code as the normal dilation process in Snippet 2. The resulting bias dilated signal is as shown in FIG. 7. The morphology filter then subtracted the first smoothed signal from the bias dilated signal (FIG. 6) to generate the down spike signal, i.e. down spikes signal=bias dilated signal—first smoothed signal, as shown in FIG. 8. The spikes in FIG. 8 indicated the positions where sharp downward steps present in the first smoothed signal (FIG. 6) and the height of the steps. Likewise, a bias erosion process was performed on the first smoothed signal for morphology labels indicating upward steps. A bias erosion process with left radius r_left=ceil(½*M_r)=2 and right radius r_right=0 was performed on the first smoothed signal (FIG. 6) to get a bias erosion signal as shown in FIG. 9. The morphology filter then subtracted the bias erosion signal from the first smoothed signal to generate the up spike signal (i.e. up spike signal=first smoothed signal—bias erosion signal), as shown in FIG. 10.

### Signal Smoothing by Moving Average Filter

The moving average filter yields the second smoothed signal which is a moving average curve used for detecting a certain trending of changes on the original input signal (FIG. 2). It averages data point values of the first smoothed signal (FIG. 6) with size of the averaging window=left_radius+right_radius. The reason why the first smoothed signal (FIG. 6) instead of the original input signal (FIG. 2) was utilized as the input of the moving average filter is that the morphology-based filter removed most glitches/spikes from the original input signal (FIG. 2).

In this example, the moving average filter in the equation form is:

$$y [ i ] = \frac{1}{( {left}_{radius} + {right}_{radius} )} {\sum }_{i = {left}_{radius}}^{j = {right}_{radius}} x [ i + j ] ,$$

where (left_radius+right_radius) is the averaging window size, x[ ] is the input data point value and y[ ] is the output data point value. The Python code for calculating moving average signal (the second smoothed signal) is shown in Snippet 7. In the code, left_radius=right_radius=floor(½*A_r), where A_r is the averaging window. The averaging window A_r was set to 6, and the resulting second smoothed signal is shown in FIG. 11.

### Generating Morphology Event Labels

In the detection stage, it processes the intermediate calculation results from both the morphology-based filter and the moving-average-based filter to find accurate downtime intervals.

First, the morphology event generator scanned both downtime spikes (as shown in FIG. 8) and uptime spikes (as shown in FIG. 10) by a morphology threshold (the down-spike threshold or the up-spike threshold) to create down events (EVENT_M_DOWN) and up events (EVENT_M_UP). These events are added to the set of morphology event labels, called m_events in the code Snippet 8. A morphology event label represents a possible downtime interval of a sudden change found by the morphology-based filter techniques. The scanning of the events was done by searching for the cross points between the threshold line and the curves, and Snippet 9 is the Python code for performing this function. A morphology event label was generated if a spike is above or equal to the morphology threshold (M_threshold), i.e. spikes value>=M_threshold.

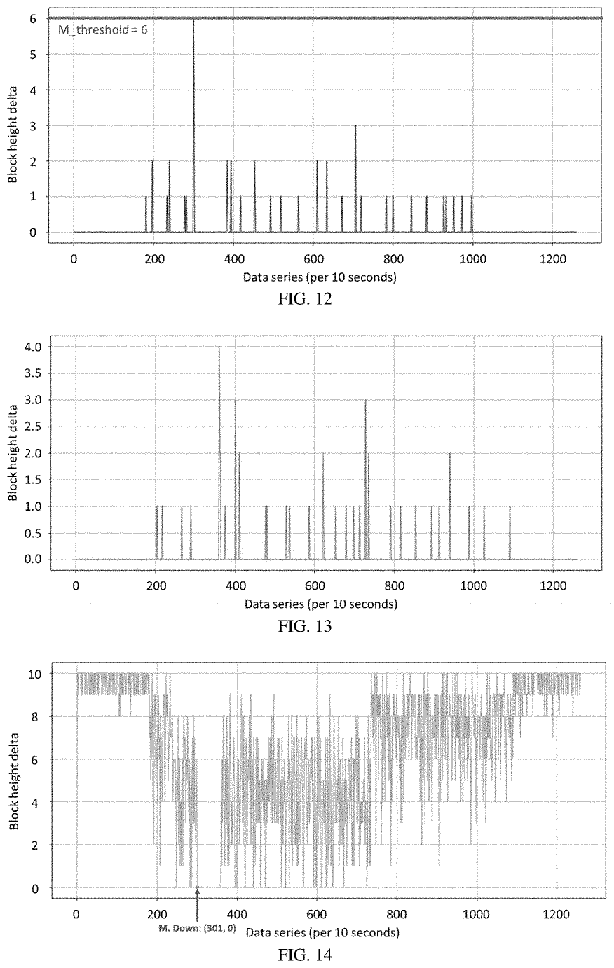

In this example, there were two types of morphology event labels—morphology down labels (M.Down) and morphology up labels (M.Up). The M.Down label was triggered by the down spikes representing a sudden drop on the original input signal (FIG. 2). Similarly, the M.Up label was triggered by the up spikes representing a sudden rise in the original input signal. The down-spike threshold was set to 6, and the down spike signal (FIG. 8) reached the threshold value, as shown in FIG. 12, which leads to an M.Down label in FIG. 14. The up-spike threshold was also set to 6, and from FIG. 13 it can be seen that none of the up spikes reached the up-spike threshold, and no M.Up label was generated.

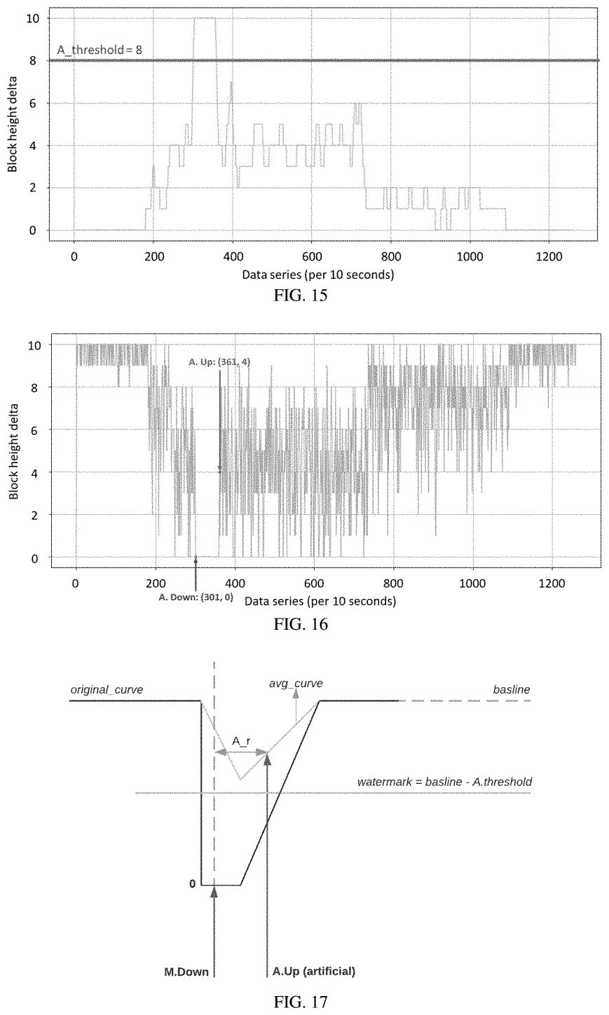

The morphology event labels not only consist of the type of change but also the index and the value on the original input signal when the radical change happened. For instance, the morphology event label in FIG. 15 is [event_type: M.Down, idx:301, value:0].

### Generating Moving Average Event Labels

The moving average event generator (abbreviated as average event generator) calculated moving average event labels (abbreviated as average event labels or a_events). In order to be able to utilize the Python code in Snippet 9, a dip function was applied first to the second smoothed signal to obtain the dip average signal as shown in FIG. 15, i.e. dip average signal=baseline—second smoothed signal. The average event labels have two types as well—average down label (A.Down) and average up label (A.Up). Since the signal was already upside-down, when the signal runs to or over the a threshold value A_threshold, i.e. dip average signal<=A_threshold, it generated an A.Up label. Conversely, when the signal ran below A_threshold, i.e. dip average signal>A_threshold, it generated an A.Down label. The A_threshold was set to 8, and the scanned result is shown in FIG. 15. The output average event labels also include the event type of the change (A.Down or A.Up), the index, and the original data value when the gradual change happened. For example, based on FIG. 15, it generated two average event labels as shown in FIG. 16, [event_type:A.Down, idx:301, value:5] and [event_type:A.Up, idx:361, value:4].

In addition, the morphology event labels were also sent to the average event generator to avoid a scenario where a down event (morphology down label) exists without any up event (morphology up label or average up label). There might be a special case that only a morphology down label (M.Down) label is generated with neither morphology up (M.Up label) nor average up label (A.Up label) to declare an uptime (i.e. the end of a downtime interval) when the system recovers, as shown in FIG. 17. To solve this problem, the average event generator is designed to insert an artificial average up label (A.filter label) if an M.Down label exists but the second smoothed signal does not run below the watermark (i.e. the dip average signal does not run above the threshold) by analyzing all existing morphology event labels. The average event labels generated by scanning by threshold and the artificial up labels were combined for the following downtime interval detection. Snippet 11 is the Python code to implement an average event generator to create average event labels (A_event).

### Detecting Downtime Interval

The downtime interval was detected by a downtime detector, in which all types of filter labels (M.filter labels and A.filter labels) were processed to calculate final downtime intervals. The followings are the steps utilized to calculate final downtime intervals in the example:
1. Merge A.filter labels and M.filter labels generated from previous steps based on the indexes to get a list of filter labels.
2. Feed the list of merged filter labels to the finite state machine in FIG. 18 to get a list of next states until there is no more input filter label. The code implementation of the finite state machine is in Snippet 15.
3. Interpret the list of states to a list of state events, where the “Up” state is converted to “UP” state event and both “Metastable Down” and “Deep Down” states are converted to “DOWN” state event.
4. Iterate the list of state events to find downtime intervals based on the following algorithm: (1) If the current state event is “DOWN” and the last state event is “UP”, a starting point of a downtime interval is declared; (2) If the current state event is “UP” and the last state event is “DOWN”, an ending point of a downtime interval is declared.

The result of the final downtime interval of the input signal is shown in FIG. 19. “Downtime: 60” means the range of the downtime interval [301, 361] including 60 data points on the original input signal. The result can also be easily verified by comparing to FIG. 14 and FIG. 16.

### Running Interval

In this example, the downtime calculation was performed periodically in a 10 mins period to avoid errors due to the boundary conditions. It read the block height increment data from the past 30 mins for calculation. The output showed the downtime interval between the last 20 mins and the last 10 mins if any downtime existed. In other words, if the filter-based downtime calculation starts at time t, it uses the block height increment data from [t−30 mins, t) for calculation and outputs the downtime interval results within the time range [t−20 mins, t−10 mins). The next run will start at t+10 mins, as shown in FIG. 20.

Below are embodiments of pseudo code for implementing the methods described above.

Pseudo code
Snippet 1. Python code to implement Morphology-based filter:

| | |
|---|---|
| 1 | # 3.1.1.# Morphology-based filter |
| 2 | def apply_morphology_filter(self): |
| 3 | original_curve = self.get_original_data_values( ) |
| 4 | radius = self.morphology_radius |
| 5 | |
| 6 | # 3.1.1.1 dilation |
| 7 | dilated_1_curve = dilate( arr=original_curve, |

r_left=radius, r_right=radius)

| | |
|---|---|
| 8 | |
| 9 | # 3.1.1.2 erosion |
| 10 | eroded_1_curve = erode( arr=dilated_1_curve, |

r_left=radius, r_right=radius)

| | |
|---|---|
| 11 | |
| 12 | # 3.1.1.3 erosion |
| 13 | eroded_2_curve = erode (arr=eroded_1_curve, |

r_left=radius, r_right=radius)

| | |
|---|---|
| 14 | |
| 15 | # 3.1.1.4 dilation |
| 16 | smoothed_curve = dilate( arr=eroded_2_curve, |

r_left=radius, r_right=radius)

| | |
|---|---|
| 17 | |
| 18 | # 3.1.1.5 dilation |
| 19 | dilated_smoothed_curve= dilate( arr=smoothed_curve, |

r_left=math.ceil(radius / 2), r_right=0)

| | |
|---|---|
| 20 | down_spikes = |

```
    subtract lists(arr_a=dilated_smoothed_curve,
    arr_b=smoothed_curve, right_offset=0)
```

| | |
|---|---|
| 21 | |
| 22 | # 3.1.1.6 erosion |
| 23 | eroded_smoothed_curve = erode(arr=smoothed_curve, |

r_left=math.ceil(radius / 2), r_right=0)

| | |
|---|---|
| 24 | up_spikes = subtract lists(arr a=smoothed_curve, |

arr_b=eroded_smoothed_curve, right_offset=0)
Snippet 2. Python code to implement the dilation operation:

| | |
|---|---|
| 1 | def_dilate(arr: list, r_left: int, r_right: int) -> list: |

# r is the radius

| | |
|---|---|
| 2 | array_mx = [ ] |
| 3 | for i in range(0, len(arr) ): |
| 4 | array_mx.append(find max(arr, i, r_left, r_right) ) |
| 5 | return array_mx |

Snippet 3. Python code to implement function of finding maximum (find_max):

| | |
|---|---|
| 1 | def find_max(arr: list, idx: int, r_left: int, r_right: |

int):

| | |
|---|---|
| 2 | end = min(len(arr) , idx + r_right + 1) |
| 3 | start = max(0, idx - r_left) |
| 4 | result = -sys.maxsize - 1 |
| 5 | for i in range(start, end): |
| 6 | result = max(arr[i], result) |
| 7 | return result |

Snippet 4. Python code to implement the erosion operation:

| | |
|---|---|
| 1 | def _erode(arr: list, r_left: int, r_right: int) -> list: |

# r is the radius

| | |
|---|---|
| 2 | array_mn = [ ] |
| 3 | for i in range(0, len(arr)): |
| 4 | array_mn.append(find min(arr, i, r_left, r_right)) |
| 5 | return array_mn |

Snippet 5. Python code to implement function of finding minimum (find_min):

| | |
|---|---|
| 1 | def find_min(arr: list, idx: int, r_left: int, r_right: |

int):

| | |
|---|---|
| 2 | end = min(len(arr) , idx + r_right + 1) |
| 3 | start = max(0, idx - r_left) |
| 4 | result = sys.maxsize |
| 5 | for i in range(start, end): |
| 6 | result = min(arr[i], result) |
| 7 | return result |

Snippet 6. Python code to implement subtraction (subtract_lists) to get down and up spikes:

| | |
|---|---|
| 1 | # arr_a - arr_b both arrays must have the same size |
| 2 | def subtract_lists(arr_a: list, arr_b: list, right_offset: |

int = @) -> list:

| | |
|---|---|
| 3 | result = [ ] |
| 4 | n = len(arr_a) |
| 5 | assert (len(arr_a) == len(arr_b) ) |
| 6 | for i in range(0, n): |
| 7 | result.append(arr_a[i] - arr_b[min(n - 1, i + |

right_off set)])

| | |
|---|---|
| 8 | return result |

Snippet 7. Python code to implement Moving-average-based filter:

| | |
|---|---|
| 1 | def apply_moving_avg(self): |
| 2 | left_radius = math.floor(0.5 * |

self. moving_average_window)

| | |
|---|---|
| 3 | right_radius = math .floor(0. 5 * |

self. moving_average_window)

| | |
|---|---|
| 4 | values = [ ] |
| 5 | for i in range(0, len(self.m_curve_values)): # array |

slide end_idx is exclusive

| | |
|---|---|
| 6 | start = max(0, i - left_radius) |
| 7 | end = min(i + right_radius + 1, |

len(self.m_curve_values) )

8

```
      values.append(int(round(mean(self.m_curve_values[start:end])
      , 0) ) )
```

| | |
|---|---|
| 9 | self.avg_curve = values |

Snippet 8. Python code to implement morphology filter event
generator to create morphology filter labels (i.e. m_event):

| | |
|---|---|
| 1 | def scan_for_m_events(self): |
| 2 | dip_threshold = self.morphology_dip_threshold |
| 3 | down_events = [ ] # type: List[FilterEvent] |
| 4 | up_events = [ ] # type: List[FilterEvent] |
| 5 | ledger_number_list = self.get_original_data_values( ) |
| 6 | |
| 7 | def m_down_trigger(event: str, idx: int, value: int) -> |

None:

| | |
|---|---|
| 8 | if event == FIRST_CONTACT: |
| 9 | down_events .append(FilterEvent(EVENT_M int) -> |

idx, value))

| | |
|---|---|
| 10 | |
| 11 | def m_up_trigger(event: str, idx: int, value: |

None:

| | |
|---|---|
| 12 | if event == FIRST_CONTACT: |
| 13 | up_events.append(FilterEvent(EVENT_M_UP_{,} |

idx, value) )

| | |
|---|---|
| 14 | |
| 15 | scan by threshold(appended_values=ledger_number_list, |
| 16 | scanned_values=self.down_spikes, |
| 17 | threshold=dip_threshold, |
| 18 | on_contact=m_down_trigger) |
| 19 | |
| 20 | scan by threshold(appended_values=ledger_number_list, |
| 21 | scanned_values=self. up_spikes, |
| 22 | threshold=dip_threshold, |
| 23 | on_contact=m_up_trigger) |
| 24 | |
| 25 | m_events = merge labels by index(down_events, |

up_events)
Snippet 9. Python code to implement scanning threshold (scan_by_threshold):

| | |
|---|---|
| 1 | def scan_by_threshold( |
| 2 | appended_values : list, scanned_values : list, |

threshold: int, on_contact: Callable[ [str, int, int]. None],

| | |
|---|---|
| 3 | on_point: Callable[ [int, int], None] = None): |
| 4 | contacted = False |
| 5 | for idx in range(0, len(scanned_values)): |
| 6 | if on_point is not None: |
| 7 | on_point(idx, appended_values[idx]) |
| 8 | if contacted: |
| 9 | if scanned_values[idx] < threshold: |
| 10 | contacted = False |
| 11 | on_contact(SECOND_CONTACT, idx, |

appended_values[idx])

| | |
|---|---|
| 12 | else: |
| 13 | if scanned_values[idx] >= threshold: |
| 14 | contacted = True |
| 15 | on_contact(FIRST_CONTACT, idx, |

appended_values[idx])

| | |
|---|---|
| 16 | |
| 17 | |
| 18 | SECOND_CONTACT = “2” |
| 19 | FIRST_CONTACT = “1” |

Snippet 10. Python code to implement merging down events (a_labels) and up events (b_labels):

| | |
|---|---|
| 1 | def merge_labels_by_index(a_labels: list, b_labels: list) |

- > list:

| | |
|---|---|
| 2 | ″″″ |
| 3 | Merge a_labels and b_labels sorted by index. When |

a_labels and b_labels has the same index, the element of

| | |
|---|---|
| 4 | a_label will go first. |
| 5 | |
| 6 | :param a_labels: |
| 7 | :param b_labels: |
| 8 | :return: |
| 9 | ″″″ |
| 10 | merged_result = [ ] |
| 11 | |
| 12 | j = i = 0 |
| 13 | while j < len(b_labels) and i < len(a_labels): |
| 14 | if int(b_labels[j].idx) < int(a_labels[i].idx): |
| 15 | merged_result.append(b_labels [ j ]) |
| 16 | j += 1 |
| 17 | else: |
| 18 | merged_result .append(a_labels[i]) |
| 19 | i += 1 |
| 20 | # check if any element was left |
| 21 | if j < len(b_labels): |
| 22 | merged_result.extend(b_labels[ j: ]) |
| 23 | if i < len(a_labels): |
| 24 | merged_result.extend (a_labels [ i: ]) |
| 25 | return merged_result |

Snippet 11. Python code to implement moving average filter event generator
to create average filter labels (i.e. A_event):

| | |
|---|---|
| 1 | def scan_for_a_events(self): |
| 2 | |
| 3 | def on_point(idx: int, value: int): |
| 4 | nonlocal last_m_event |
| 5 | if len(_m_events) > 0: |
| 6 | if idx >= _m_events[0].idx: |
| 7 | # pop the m_filter if we scan pass the |

label.

| | |
|---|---|
| 8 | last_m_event = _m_events.pop(0) |
| 9 | downtime_state.trigger(last_m_event) |
| 10 | |
| 11 | if downtime_state.get_state( ) == STATE_DOWN: |
| 12 | if (idx - last_m_event.idx) > |

moving_average_window:

| | |
|---|---|
| 13 | # special case: If the moving average |

```
    is above the watermark since the last DOWN event and is
    longer than the moving average window, and then we insert a
    A_UP event.
```

| | |
|---|---|
| 14 | |
| 15 | _event = FilterEvent(EVENT_A_UP, idx, |

value)

| | |
|---|---|
| 16 | downtime_state.trigger(_event) |
| 17 | _a_events.append(_event) |
| 18 | |
| 19 | def on_contact (contact: str, idx: int, value: int) -> |

None:

| | |
|---|---|
| 20 | if contact == FIRST_CONTACT: |
| 21 | _event = FilterEvent(EVENT_A_DOWN, idx, value) |
| 22 | elif contact == SECOND_CONTACT: |
| 23 | _event = FilterEvent(EVENT_A_UP, idx, value) |
| 24 | else: |
| 25 | assert False |
| 26 | |
| 27 | _a_events.append(_event) |
| 28 | downtime_state.trigger(_event) |
| 29 | |
| 30 | # initialize variables |
| 31 | dip_threshold = self.moving_average_dip_threshold |
| 32 | moving_average_window = self.moving_average_window |
| 33 | _a_events = [ ] # type: List[FilterEvent] |
| 34 | _m_events = [ ] # type: List[FilterEvent] |
| 35 | ledger_number_list = self.get_original_data_values( ) |
| 36 | last_m_event = None |
| 37 | |
| 38 | # copy the m_event list |
| 39 | for event in self.m_events: |
| 40 | _m_events.append(event) |
| 41 | downtime_state = DowntimeState(STATE_UP) |
| 42 | values = inverse(self.avg_curve) |
| 43 | self.dip_avg_curve = offset(values, self.base_line) |
| 44 | self.plot_dip_avg_curve( ) |
| 45 | |
| 46 | scan by threshold(appended_values=ledger_number_list, |
| 47 | scanned_values=self.dip_avg_curve, |
| 48 | threshold=dip_threshold, |
| 49 | on_contact=on_contact, |
| 50 | on_point=on_point) |
| 51 | |
| 52 | self.a_events = _a_events |

Snippet 12. Python code to implement inverse function:

| | |
|---|---|
| 1 | def inverse(values: list): |
| 2 | result = [None] * len(values) |
| 3 | for i in range(0, len(values)): |
| 4 | result[i] = values[i] * -1 |
| 5 | return result |

Snippet 13. Python code to implement offset function:

| | |
|---|---|
| 1 | def offset (values: list, offset value: int): |
| 2 | result = [None] * len(values) |
| 3 | for i in range(0, len(values)): |
| 4 | result[i] = values[i] + offset_value |
| 5 | return result |

Snippet 14. Python code to implement downtime interval detection:

| | |
|---|---|
| 1 | def find_downtime_intervals(self) : |
| 2 | _a_events = [ ] # type: List[FilterEvent ] |
| 3 | _m_events = [ ] # type: List[FilterEvent] |
| 4 | # copy the m_events and a_events list |
| 5 | for m_event in self.m_events: |
| 6 | _m_events.append(m_event) |
| 7 | for a_event in self.a_events: |
| 8 | _a_events.append(a_event) |
| 9 | |
| 10 | # merge m_labels with a_labels and sort by index, |
| 11 | _events = [ ] # type: List[FilterEvent] |
| 12 | _events = merge labels by index(a_labels=_a_events, |

b_labels=_m_events)

| | |
|---|---|
| 13 | |
| 14 | # Run the finite state machine |
| 15 | downtime_state = DowntimeState(STATE_UP) |
| 16 | state_events = [ ] # type: List[StateEvent] |
| 17 | for _event in _events: |
| 18 | _last_state = downtime_state.get_state( ) |
| 19 | if _last_state != downtime_state.trigger(_event): |
| 20 | if downtime_state.get_state( ) == STATE_DOWN or |

downtime_state.get_state( ) == STATE_DEEP_DOWN:

| | |
|---|---|
| 21 | state_events. append(StateEvent(″DOWN″ , |

_event.idx, _event.value))

| | |
|---|---|
| 22 | else: |
| 23 | state_events. append(StateEvent(″UP″, |

_event.idx, _event.value))

| | |
|---|---|
| 24 | |
| 25 | # Declare down time interval |
| 26 | intervals = [ ] # type: List[DowntimeInterval] |
| 27 | if len(state_events) > 0: |
| 28 | last_state_event_type = ″UP″ |
| 29 | start = end = None |
| 30 | for state_event in state_events: |
| 31 | if last_state_event_type == ″UP″ and |

state_event.type == ″DOWN″:

| | |
|---|---|
| 32 | start = state_event |
| 33 | elif last_state_event_type == ″Down″ and |

state_event.type == ″UP″:

| | |
|---|---|
| 34 | end = state_event |
| 35 | |
| 36 | last_state_event_type = state_event.type |
| 37 | |
| 38 | if start is not None and end is not None: |
| 39 | intervals.append(Downtimelnterval(start, |

end, end.idx - start.idx))

| | |
|---|---|
| 40 | start = None |
| 41 | end = None |
| 42 | # if the curve does not recover till the end |
| 43 | if start is not None and end is None: |
| 44 | end = StateEvent(event_type=″DOWN″ , |

idx=self.get_data_size( ) - 1,

45

value=self.get_original_data_values( )[ -1 ])

| | |
|---|---|
| 46 | intervals.append(DowntimeInterval(start, end, |

end.idx - start.idx))

| | |
|---|---|
| 47 | self.intervals = intervals |

Snippet 15. Python code to implement the finite state
machine ([FIG. 17]) in the downtime interval detection:

| | |
|---|---|
| 1 | class SloEvent: |
| 2 | def __init__(self, event_type: str, idx: int, value: |

int):

| | |
|---|---|
| 3 | self.type = event_type |
| 4 | self.idx = idx |
| 5 | self.value = value |
| 6 | |
| 7 | |
| 8 | class FilterEvent(SloEvent): |
| 9 | def _repr__(self): |
| 10 | return ″[event_type:{ }, idx:{ }, |

value:{ }]″.format(self.type, self.idx, self.value)

| | |
|---|---|
| 11 | |
| 12 | |
| 13 | class StateEvent(SloEvent): |
| 14 | def __repr__(self): |
| 15 | return ″[state_type:{ }, idx:{ }, |

value:{ }″.format(self.type, self.idx, self.value)

| | |
|---|---|
| 16 | |
| 17 | |
| 18 | class DowntimeInterval: |
| 19 | # intervals.append((start, end, end.idx - start.idx)) |
| 20 | def __init__(self, start_event: StateEvent, |

end_event: StateEvent, interval: int):

| | |
|---|---|
| 21 | self.start_event = start_event |
| 22 | self.end_event = end_event |
| 23 | self.interval = interval |
| 24 | |
| 25 | def __repr__(self): |
| 26 | return ″[start: { }, end: { }, |

```
    interval:{ }]″ .format(self.start_event, self.end_event,
    self.interval)
```

| | |
|---|---|
| 27 | |
| 28 | |
| 29 | # finite state machine: phase I |
| 30 | class State: |
| 31 | def __init__(self, name): |
| 32 | self.name = name |
| 33 | |
| 34 | def next(self, event: FilterEvent ): |
| 35 | assert 0, ″next not implemented″ |
| 36 | |
| 37 | |
| 38 | class UpState(State) : |
| 39 | def next(self, event: FilterEvent): |
| 40 | if event.type == EVENT_A_UP: |
| 41 | return STATE_UP |
| 42 | if event.type == EVENT_A_DOWN: |
| 43 | return STATE_DEEP_DOWN |
| 44 | if event.type == EVENT_M_UP: |
| 45 | return STATE_UP |
| 46 | if event.type == EVENT_M_DOWN : |
| 47 | return STATE_DOWN |
| 48 | assert False |
| 49 | |
| 50 | |
| 51 | class DownState(State): |
| 52 | def next(self, event: FilterEvent): |
| 53 | if event.type == EVENT_A_UP: |
| 54 | return STATE_UP |
| 55 | if event.type == EVENT_A_DOWN: |
| 56 | return STATE_DEEP_DOWN |
| 57 | if event.type == EVENT_M_UP: |
| 58 | return STATE_UP |
| 59 | if event.type == EVENT_M_DOWN : |
| 60 | return STATE_DOWN |
| 61 | assert False |
| 62 | |
| 63 | |
| 64 | class DeepDownState(State) : |
| 65 | def next(self, event: FilterEvent): |
| 66 | if event.type == EVENT_A_UP: |
| 67 | return STATE_UP |
| 68 | if event.type == EVENT_A_DOWN: |
| 69 | return STATE_DEEP_DOWN |
| 70 | if event.type == EVENT_M_UP: |
| 71 | return STATE_DEEP_DOWN |
| 72 | if event.type == EVENT_M_DOWN : |
| 73 | return STATE_DEEP_DOWN |
| 74 | assert False |
| 75 | |
| 76 | |
| 77 | class Downtimestate: |
| 78 | def __init__(self, state: State): |
| 79 | self.current_state = state |
| 80 | |
| 81 | def trigger(self 3 event: FilterEvent) |
| 82 | self.current_state = |

self.current_state.next(event)

| | |
|---|---|
| 83 | return self.current_state |
| 84 | |
| 85 | |
| 86 | def get_state(self) -> State: |
| 87 | return self.current_state |
| 88 | |
| 89 | |
| 90 | EVENT_A_UP = ″A.Up″ |
| 91 | EVENT_A_DOWN = ″A.Down″ |
| 92 | EVENT_M_UP = ″M.Up″ |
| 93 | EVENT_M_DOWN = ″M.Down″ |
| 94 | STATE_UP = UpState(″UP″) |
| 95 | STATE_DOWN = Downstate (″DOWN″) |
| 96 | STATE_DEEP_DOWN = DeepDownState(″DEEP_DOWN″ ) |

The foregoing description of embodiments is provided to enable any person skilled in the art to make and use the subject matter. Various modifications to these embodiments will be readily apparent to those skilled in the art, and the novel principles and subject matter disclosed herein may be applied to other embodiments without the use of the innovative faculty. The claimed subject matter set forth in the claims is not intended to be limited to the embodiments shown herein but is to be accorded the widest scope consistent with the principles and novel features disclosed herein. It is contemplated that additional embodiments are within the spirit and true scope of the disclosed subject matter. Thus, it is intended that the present invention covers modifications and variations that come within the scope of the appended claims and their equivalents.

What is claimed is:

1. A method for signal processing, comprising filtering an input signal from a system by a closing process and an opening process to generate a first smoothed signal, wherein:
the closing process comprises a first dilation process followed by a first erosion process; and
the opening process comprises a second erosion process followed by a second dilation process.

2. The method of claim 1, wherein each of the first dilation process and the second dilation process is performed by:
for each data point of the input signal, outputting its local maximum within a normal dilation window; and
wherein each of the first erosion process and the second erosion process is performed by:
for each data point of the input signal, outputting its local minimum within a normal erosion window.

3. The method of claim 2, wherein the position of each outputted local maximum is at the center of the corresponding normal dilation window.

4. The method of claim 2, wherein the position of each outputted local minimum is at the center of the corresponding normal erosion window.

5. A method of claim 2, further comprising:
generating, by a moving average filter, a second smoothed signal, wherein each data point of the second smoothed signal is generated by:
for each data point of the first smoothed signal, calculating the average value of all local data points within an averaging window, and outputting the averaging result.

6. The method of claim 5, wherein the position of each outputted averaging result is at the center of the corresponding averaging window.

7. A method of claim 5, further comprising:
generating, by a morphology event generator, a series of morphology event labels representing system down events or up events based on the first smoothed signal, wherein the series of morphology event labels indicating the positions of sharp downward steps and sharp upward steps of the first smoothed signal;
generating, by an average event generator, a series of average event labels representing system down events or up events based on the second smoothed signal, wherein the series of average event labels indicating the positions where the second smoothed signal crosses an average threshold value.

8. A method of claim 7, further comprising:
determining, by a downtime detector, one or more downtime intervals based on the morphology event labels and the average event labels, wherein each of the downtime intervals indicates the interval when the system does not operate normally.

9. The method of claim 7, wherein:
the morphology event labels comprise a series of morphology down labels indicating the positions of sharp downward steps of the first smoothed signal, and a series of morphology up labels indicating the positions of sharp upward steps of the first smoothed signal; and
the average event labels comprise a series of average down labels indicating the positions where the second smoothed signal crosses the average threshold value from above to below, and a series of average up labels indicating the positions where the second smoothed signal crosses the average threshold value from below to above.

10. The method of claim 9, wherein the positions of sharp downward steps are identified by:
performing a bias dilation process to the first smoothed signal to generate a bias dilated signal;
subtracting each data point of the first smoothed signal from the corresponding data point of the bias dilated signal to obtain a first spike signal representing the positions of downward steps; and
finding the positions where the value of the first spike signal is equal to or above a down-spike threshold value.

11. The method of claim 10, wherein the bias dilation process is performed by:
for each data point of the first smoothed signal, outputting its local maximum within a bias dilation window, wherein the position of each outputted local maximum is at the last position of the corresponding bias dilation window.

12. The method of claim 11, wherein the bias dilation window is smaller than half of the normal dilation window.

13. The method of claim 9, wherein the positions of sharp upward steps are identified by:
performing a bias erosion process to the first smoothed signal to generate a bias eroded signal;
subtracting each data point of the bias eroded signal from the corresponding data point of the first smoothed signal to obtain a second spike signal representing the position of upward steps; and
finding the positions where the value of the second spike signal is equal to or above an up-spike threshold value.

14. The method of claim 13, wherein the bias erosion process is performed by:
for each data point of the first smoothed signal, outputting its local minimum within a bias erosion window, wherein the position of each outputted local minimum is at the last position of the corresponding bias erosion window.

15. The method of claim 14, wherein the bias erosion window is smaller than half of the normal erosion window.

16. The method of claim 9, wherein the series of average up labels further comprise a series of artificial up labels indicating the second smoothed signal goes above the average threshold value following a morphology down label.

17. The method of claim 16, wherein each of the artificial up labels is generated when a morphology down label is identified but all values of the second smoothed signal within a predetermined range from which the morphology down label is identified are above the average threshold value.

18. The method of claim 17, wherein the predetermined range is the same as the averaging window.

19. The method of claim 16, further comprising:
determining, by a downtime detector, a downtime interval based on the morphology event labels and the average event labels, wherein the downtime interval indicates the interval when the system does not operate normally.

20. The method of claim 19, wherein the downtime interval is determined by a state machine with multiple states with the steps of:
integrating the morphology event labels and the average event labels into the same index based on their corresponding positions;
determining the state of the first position in region of interest;
determining the state of each position from the second position to the last position in region of interest based on the state of its previous position and the existence of a morphology event label or an average event label at that position; and
determining the downtime interval based on the states of all positions in the region of interest.

21. The method of claim 20, wherein:
if a morphology event label and an average event label are present at the same position when integrating the series of morphology event labels and the series of average event labels, only the average event label at the position is entered.

22. The method of claim 20, wherein:
the states in the state machine comprise Up state, Metastable Down state and Deep Down state;
the state of the first position is set to Up state; and
the state of the remaining position are determined by the following rules:
if no morphology event label or average event label is identified at that position, the state of the position is the same as the previous position;
if an average up label is identified at that position, the state of the position is Up state;
if an average down label is identified at that position, the state of the position is Deep Down state;
if the previous position is Up state or Metastable Down state, and a morphology up label is identified at that position, the state of the position is Up state;
if the previous position is Up state or Metastable Down state, and a morphology down label is identified at that position, the state of the position is Metastable Down state; and
if the previous position is Deep Down state and a morphology up label or a morphology down label is identified at that position, the state of the position is Deep Down state.

23. The method of claim 22, wherein the downtime interval is determined by:
identifying the positions determined as Metastable Down state or Deep Down state where the previous state is Up state as the starting points of downtime;
identifying the positions determined as Up state where the previous state is Metastable Down state or Deep Down state as the ending points of downtime; and
pairing all staring points of downtime with their following ending points of downtime to identify all downtime intervals.

24. The method of claim 23, further comprising calculating the length of each downtime interval.

25. The method of claim 24, further comprising summing up the length of all downtime intervals to determine a total downtime of the system within a region of interest.

26. The method of claim 19, wherein the interval of downtime determination is smaller than the interval of state determination.
